(19) United States
(12) Patent Application Publication
(10) Pub. No.: US 2026/0129818 A1
(43) Pub. Date: May 7, 2026

(54) DUAL-SIDED MOLD GRID ARRAY WITH A COPPER POST ISOLATION WALL AND METHOD OF FORMING SAME

(71) Applicant: SKYWORKS SOLUTIONS, INC., Irvine, CA (US)

(72) Inventor: Howard E. Chen, Anaheim, CA (US)

(21) Appl. No.: 19/369,584

(22) Filed: Oct. 27, 2025

Related U.S. Application Data
(60) Provisional application No. 63/716,424, filed on Nov. 5, 2024.
(60) Provisional application No. 63/716,422, filed on Nov. 5, 2024.

(51) Int. Cl. H05K 9/00; H05K 5/02

(52) U.S. Cl. CPC H05K 9/0007; H05K 5/0217

(57) ABSTRACT

An electronic package for mounting to a circuit board is provided. The electronic package comprises a substrate, and first and second electronic modules. The substrate has opposed first and second sides. The first and second electronic modules are disposed on the second side of the substrate to be spaced apart from each other. Third and fourth electronic modules are disposed on the first side of the substrate and spaced apart from each other. The electronic package also comprises at least one wall section disposed between the first and second electronic modules. The at least one wall section is mounted on the second side of the substrate. The at least one wall section is configured to electromagnetically shield the first and second electronic modules from each other. Further provided are methods of forming the electronic package.

### CROSS-REFERENCE TO RELATED APPLICATIONS

This application claims priority under 35 U.S.C. § 119(e) to U.S. Provisional Patent Application Serial No. 63/716,422, titled “DUAL-SIDED MOLD GRID ARRAY WITH A COPPER POST ISOLATION WALL”, filed November 5, 2024, and to U.S. Provisional Patent Application Serial No. 63/716,424, titled “METHOD OF FORMING A DUAL-SIDED MOLD GRID ARRAY WITH A COPPER POST ISOLATION WALL”, filed November 5, 2024, the entire content of each being incorporated herein by reference for all purposes.

### BACKGROUND

### Field

The present disclosure relates to an electronic package for mounting to a circuit board. The present disclosure also relates to an electronic device comprising an electronic package mounted to a circuit board. The present disclosure also relates to a method of manufacturing an electronic package.

### Description of the Related Technology

Conventional electronic packages may have two or more electronic modules mounted to a bottom side of a substrate panel of the electronic package. To avoid or reduce radio frequency electromagnetic radiation emissions from one of the electronic modules adversely affecting operation of the other of the electronic modules, the electronic modules may be separated from each other by a line of solder balls, the line of solder balls forming part of a ball grid array. The solder balls of the ball grid array are arranged in a grid of rows and columns, with adjacent ones of the solder balls separated from each other by a predetermined pitch. The primary function of the solder balls of the ball grid array is to allow the electronic package to be coupled to a separate circuit board. The line of solder balls located between the two electronic modules serves as a form of electromagnetic shielding to reduce radio-frequency (RF) electromagnetic radiation emissions from one of the electronic modules adversely affecting operation of the other of the electronic modules.

### SUMMARY

According to one embodiment, there is provided an electronic package for mounting to a circuit board. The electronic package comprises a substrate having opposed first and second sides, first and second electronic modules disposed on the second side of the substrate and spaced apart from each other, third and fourth electronic modules disposed on the first side of the substrate and spaced apart from each other, at least one wall section disposed between the first and second electronic modules, the at least one wall section mounted on the second side of the substrate, the at least one wall section being configured to electromagnetically shield the first and second electronic modules from each other.

In one example, the at least one wall section is coupled to at least one of a plurality of interfaces provided on the second side of the substrate.

In one example, the at least one wall section is integrally formed as a unitary piece with the at least one of the plurality of interfaces.

In one example, the at least one wall section is electroplated onto the at least one of the plurality of interfaces.

In one example, the at least one wall section is coupled to two or more of the plurality of interfaces.

In one example, the at least one wall section is substantially formed of an electrically conductive material.

In one example, the at least one wall section is substantially formed of copper.

In one example, the at least one of the plurality of interfaces is formed of an electrically conductive material.

In one example, the at least one wall section and the at least one of plurality of interfaces are formed of a same material.

In one example, the at least one wall section and the at least one of the plurality of interfaces are each substantially formed of copper.

In one example, the first side of the substrate corresponds to a top surface of the electronic package and the second side of the substrate corresponds to a bottom surface of the electronic package.

In one example, the bottom surface of the electronic package is configured for mounting to a surface of a separate circuit board.

In one example, the plurality of interfaces comprises a grid of rows and columns of the plurality of interfaces.

In one example, the at least one wall section is coupled to at least one of the plurality of interfaces and offset from a center of the at least one of the plurality of interfaces .

In one example, an intermediate element couples the at least one wall section to the at least one of the plurality of interfaces.

In one example, the intermediate element comprises or consists of a solder ball.

In one example, the at least one of the plurality of interfaces comprises a metallic contact pad.

In one example, the metallic contact pad is coupled to a via extending from the first side of the substrate.

In one example, the metallic contact pad is integrally formed as a unitary piece with the via.

In one example, the at least one wall section extends over the second side of the substrate along a linear path between opposed ends of the at least one wall section.

In one example, the at least one wall section extends around at least 50%, or at least 60%, or at least 70% of a perimeter of one of the first and second electronic modules.

In one example, the at least one wall section extends around an entire perimeter of the one of the first and second electronic modules.

In one example, the at least one wall section has a thickness of between 0.05 mm and 1 mm. In other examples, the thickness of the at least one wall section may be greater or lesser in value.

In one example, the at least one wall section extends over at least 50%, or at least 60%, or at least 75%, or at least 85%, or at least 95% of a length of an overlap region between opposing side faces of the first and second electronic modules. In other examples, the at least one wall section may extend over a lesser percentage proportion of the length of the overlap region.

In one example, the at least one wall section comprises a plurality of wall sections.

In one example, the plurality of wall sections are successively arranged to extend around at least 50%, or at least 60%, or at least 70% of a perimeter of one of the first and second electronic modules.

In one example, the plurality of wall sections are successively arranged to extend around an entire perimeter of one of the first and second electronic modules.

In one example, first and second ones of the plurality of wall sections are disposed on the second side of the substrate and aligned substantially perpendicular to each other.

In one example, a clearance is provided between adjacent first and second ones of the plurality of wall sections.

In one example, the clearance is 0.05 mm or more. In other examples, the clearance may be smaller in value.

In one example, the at least one wall section extends away from the second side of the substrate to a height of no more than 130 microns, or no more than 120 microns, or no more than 110 microns, or no more than 100 microns. In other examples, the height of the at least one wall section may exceed these values.

In one example, one or more solder portions are disposed on an exposed surface of the at least one wall section for coupling the electronic package to a separate circuit board.

In one example, a second side mold structure extends over at least part of the second side of the substrate to at least partially encapsulate the at least one wall section.

In one example, the at least one wall section is fully encapsulated within the second side mold structure.

In one example, a face of the at least one wall section is exposed through the second side mold structure.

In one example, the exposed face of the at least one wall section is flush with an exposed surface of the second side mold structure.

In one example, one or more solder portions are disposed on an exposed surface of the at least one wall section for coupling the electronic package to a separate circuit board.

In one example, the electronic package is a dual-sided electronic package.

According to another embodiment, there is provided an electronic device including an electronic sub-assembly. The electronic sub-assembly comprises a circuit board, and an electronic package mounted to the circuit board. The electronic package includes a substrate having opposed first and second sides, first and second electronic modules disposed on the second side of the substrate to be spaced apart from each other, at least one wall section disposed between the first and second electronic modules, the at least one wall section mounted on the second side of the substrate, the at least one wall section configured to electromagnetically shield the first and second electronic modules from each other.

In one example, the electronic device is a wireless mobile device.

According to another embodiment, there is provided a method for manufacturing an electronic package for mounting to a circuit board. The method comprises providing a substrate having opposed first and second sides, arranging first and second electronic modules on the second side of the substrate to be spaced apart from each other, arranging third and fourth electronic modules on the first side of the substrate to be spaced apart from each other, and arranging or forming at least one wall section on the second side of the substrate between the first and second electronic modules, the at least one wall section being configured to electromagnetically shield the first and second electronic modules from each other.

In one example, arranging or forming the at least one wall section on the second side of the substrate comprises coupling the at least one wall section to at least one of a plurality of interfaces provided on the second side of the substrate.

In one example, arranging or forming the at least one wall section on the second side of the substrate comprises integrally forming the at least one wall section as a unitary piece with at least one of the plurality of interfaces.

In one example, arranging or forming the at least one wall section on the second side of the substrate comprises electroplating the at least one wall section onto at least one of the plurality of interfaces.

In one example, arranging or forming the at least one wall section on the second side of the substrate comprises coupling the at least one wall section to two or more of the plurality of interfaces.

In one example, arranging the first and second electronic modules on the second side of the substrate precedes arranging or forming the at least one wall section on the second side of the substrate.

In one example, arranging or forming the at least one wall section on the second side of the substrate precedes arranging the first and second electronic modules on the second side of the substrate.

In one example, the at least one wall section is substantially formed of an electrically conductive material.

In one example, the at least one wall section is substantially formed of copper.

In one example, the at least one of the plurality of interfaces is formed of an electrically conductive material.

In one example, the at least one wall section and the at least one of the plurality of interfaces are formed of a same material.

In one example, the at least one wall section and the at least one of the plurality of interfaces are each substantially formed of copper.

In one example, the first side of the substrate corresponds to a top surface of the electronic package and the second side of the substrate corresponds to a bottom surface of the electronic package.

In one example, the bottom surface of the electronic package is configured for mounting to a surface of a separate circuit board.

In one example, the plurality of interfaces define a grid of rows and columns of the plurality of interfaces.

In one example, arranging or forming the at least one wall section on the second side of the substrate is performed such that the at least one wall section is coupled to at least one of the plurality of interfaces and is offset from a center of the at least one of the plurality of interfaces.

In one example, arranging or forming the at least one wall section on the second side of the substrate comprises coupling the at least one wall section to at least one of the plurality of interfaces using an intermediate element positioned therebetween.

In one example, the intermediate element comprises or consists of a solder ball.

In one example, the at least one of the plurality of interfaces comprises a metallic contact pad.

In one example, the metallic contact pad is coupled to a via extending from the first side of the substrate.

In one example, the metallic contact pad is integrally formed as a unitary piece with the via.

In one example, arranging or forming the at least one wall section on the second side of the substrate is performed such that the at least one wall section extends over the second side of the substrate along a linear path between opposed ends of the at least one wall section.

In one example, arranging or forming the at least one wall section on the second side of the substrate is performed such that the at least one wall section extends around at least 50%, or at least 60%, or at least 70% of a perimeter of one of the first and second electronic modules.

In one example, arranging or forming the at least one wall section on the second side of the substrate is performed such that the at least one wall section extends around an entire perimeter of the one of the first and second electronic modules.

In one example, the at least one wall section is provided or formed to have a wall thickness of between 0.05 mm and 1 mm. In other examples, the thickness of the at least one wall section may be greater or lesser in value.

In one example, the first and second electronic modules are arranged on the second side of the substrate and the at least one wall section is arranged or formed on the second side of the substrate such that the at least one wall section extends over at least 50%, or at least 60%, or at least 75%, or at least 85%, or at least 95% of a length of an overlap region between opposing side faces of the first and second electronic modules. In other examples, the at least one wall section may extend over a lesser percentage proportion of the length of the overlap region.

In one example, arranging or forming the at least one wall section on the second side of the substrate comprises arranging or forming a plurality of wall sections on the second side of the substrate.

In one example, the first and second electronic modules are arranged on the second side of the substrate and the plurality of wall sections are arranged or formed on the second side of the substrate such that the plurality of wall sections are successively arranged to extend around at least 50%, or at least 60%, or at least 70% of a perimeter of one of the first and second electronic modules.

In one example, the first and second electronic modules are arranged on the second side of the substrate and the plurality of wall sections are arranged or formed on the second side of the substrate such that the plurality of wall sections are successively arranged to extend around an entire perimeter of one of the first and second electronic modules.

In one example, arranging or forming the plurality of wall sections on the second side of the substrate comprises arranging or forming first and second ones of the plurality of wall sections on the second side of the substrate to be aligned substantially perpendicular to each other.

In one example, arranging or forming the plurality of wall sections on the second side of the substrate comprises providing a clearance between adjacent first and second ones of the plurality of wall sections.

In one example, the clearance is 0.05 mm or more. In other examples, the clearance may be smaller in value.

In one example, the at least one wall section is arranged or formed on the second side of the substrate such that the at least one wall section extends away from the second side of the substrate to a height of no more than 130 microns, or no more than 120 microns, or no more than 110 microns, or no more than 100 microns. In other examples, the height of the at least one wall section may exceed these values.

In one example, the method further comprises providing one or more solder portions on an exposed surface of the at least one wall section for coupling the electronic package to a separate circuit board.

In one example, the method further comprises arranging a second side mold structure over at least part of the second side of the substrate to at least partially encapsulate the at least one wall section.

In one example, the second side mold structure is arranged over the at least part of the second side of the substrate to fully encapsulate the at least one wall section within the second side mold structure.

In one example, the method further comprises removing a portion of the second side mold structure to expose a face of the at least one wall section through the second side mold structure.

In one example, removing the portion of the second side mold structure is performed such that the exposed face of the at least one wall section is flush with an exposed surface of the second side mold structure.

In one example, the method further comprises disposing one or more solder portions on the exposed face of the at least one wall section for coupling the electronic package to a separate circuit board.

In one example, the electronic package resulting from the method is a dual-sided electronic package.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment,” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the aspects and embodiments disclosed herein. In the figures, each identical or nearly identical component that is illustrated in various figures is represented by a like numeral. For purposes of clarity, not every component may be labeled in every figure. In the figures:

FIG. 1 is a plan schematic view of the bottom side of an electronic package according to the background art.

FIG. 2 is a cross-sectional schematic view through section A-A of the electronic package of FIG. 1.

FIG. 3 is a plan schematic view of the bottom side of a first example of an electronic package according to aspects of the present disclosure.

FIG. 4 is a cross-sectional schematic view through section B-B of the electronic package of FIG. 3.

FIG. 5 is a cross-sectional schematic view through section C-C of the electronic package of FIG. 3.

FIG. 6 is a cross-sectional schematic view through section D-D of the bottom half of the electronic package of FIG. 3, showing one of two electromagnetic shield walls formed on a bottom side of the electronic package between adjacent electronic modules.

FIG. 7 is a cross-sectional schematic view through section E-E of the bottom half of the electronic package of FIG. 3, showing a second of two electromagnetic shield walls formed on the bottom side of the electronic package.

FIG. 8 is a cross-sectional schematic view through section F-F of the bottom half of the electronic package of FIG. 3, showing a post of a grid of metallic posts formed on the bottom side of the electronic package.

FIG. 9 is a cross-sectional schematic view through section E-E of the bottom half of the electronic package of FIG. 3, showing an alternative embodiment of how an electromagnetic shield wall may be formed on the bottom side of the electronic package between adjacent electronic modules.

FIG. 10 is a plan schematic view of the bottom side of a further example of an electronic package according to aspects of the present disclosure.

FIG. 11 is a schematic view showing the electronic package of FIG. 3 mounted to a surface of a separate circuit board to form an electronic sub-assembly, the electronic package shown through section B-B of FIG. 3.

FIG. 12 is a flow chart illustrating an exemplary method of manufacturing an electronic package, for example, the electronic package of FIG. 3, according to aspects of the present disclosure.

FIG. 13 shows one or more electronic packages mounted on a wireless phone board that can include one or more features described herein.

FIG. 14 schematically depicts the wireless phone board with an electronic package according to the present disclosure installed thereon.

FIG. 15 schematically depicts a wireless device incorporating the wireless phone board of FIG. 14 with the electronic package installed thereon.

### DETAILED DESCRIPTION

Aspects and embodiments described herein are directed to an electronic package, preferably a dual-sided electronic package, for mounting to a circuit board. Aspects and embodiments described herein are also directed to an electronic device including an electronic package. Aspects and embodiments described herein are also directed to a method for manufacturing an electronic package for mounting to a circuit board. Aspects and embodiments described herein provide for a more space efficient and adaptable design for avoiding or reducing RF electromagnetic interference between adjacent electronic modules mounted to a bottom side of an electronic package.

It is to be appreciated that embodiments of the packages, devices, and methods discussed herein are not limited in application to the details of construction and the arrangement of components set forth in the following description or illustrated in the accompanying drawings. The packages, devices, and methods are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

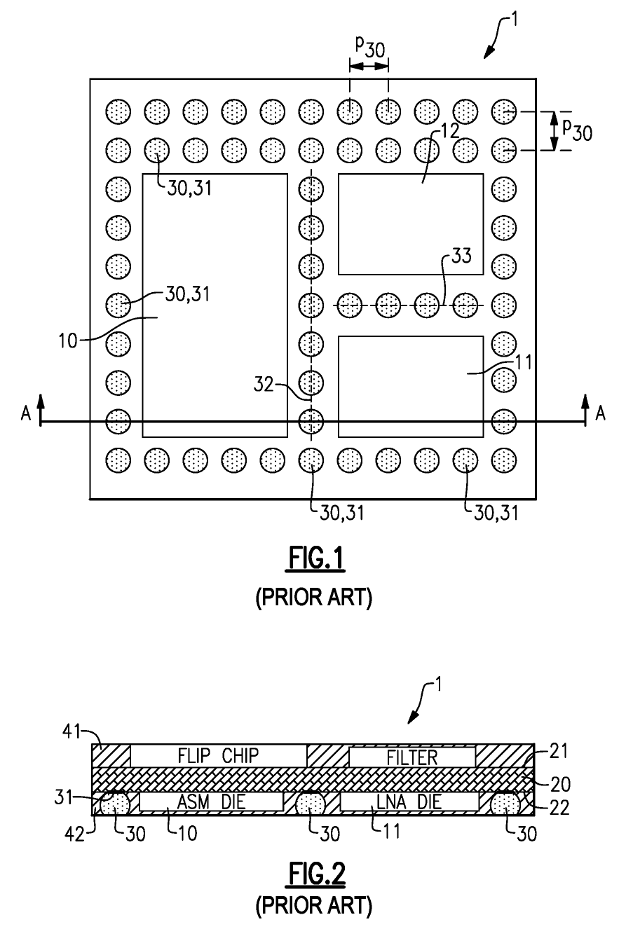

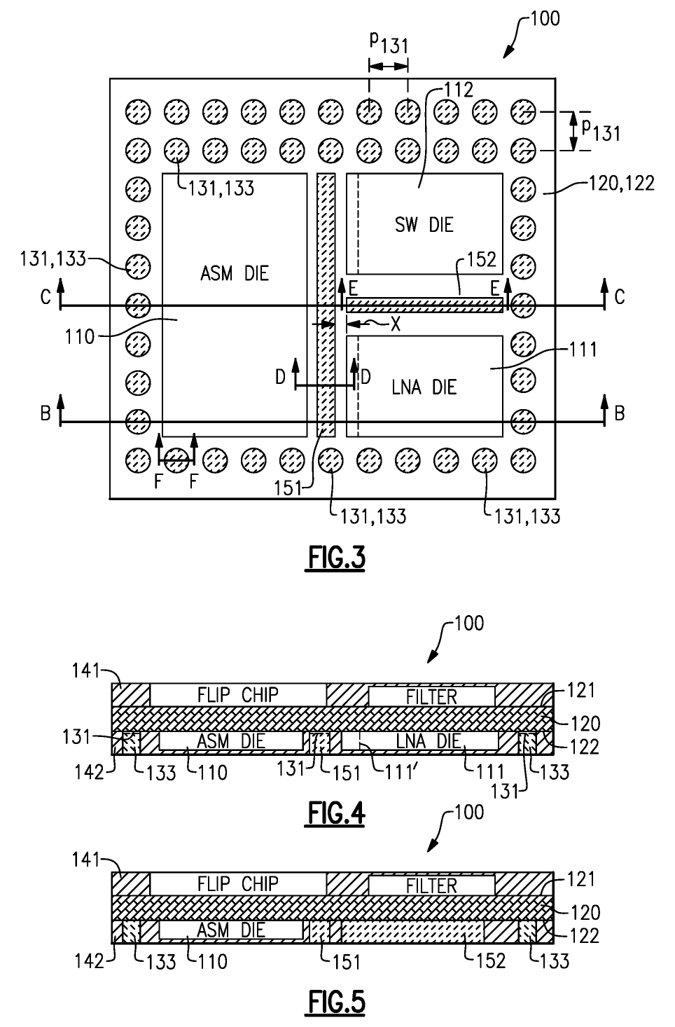

FIG. 1 shows a plan schematic view of a bottom side of an electronic package 1 of the background art. FIG. 2 shows a cross-sectional schematic view through section A-A of the electronic package 1 of FIG. 1. Electronic modules are mounted to upper and lower surfaces 21, 22 of a substrate panel 20 of the electronic package 1. A flip chip and filter are shown mounted to the upper surface 21 of the substrate panel 20. The electronic modules mounted to the lower surface 22 of the substrate panel 20 include three semiconductor dies 10, 11, 12. A ball grid array 30 of solder balls is also arranged over the lower surface 22 of the substrate panel 20. The ball grid array 30 is arranged as grid formed of a series of rows and columns of the solder balls. The ball grid array 30 of solder balls is arranged around the semiconductor dies 10, 11, 12. Each of the solder balls of the ball grid array 30 is fused to a corresponding metal contact pad of a grid of metal contact pads 31 provided on the lower surface 22 of the substrate panel. The solder balls of the ball grid array 30 are centrally positioned on their respective contact pads 31. Each of the solder balls is separated from adjacent ones of the solder balls by a predetermined pitch ‘p₃₀’. The pitch ‘p₃₀’ also corresponds to the pitch between adjacent ones of the contact pads 31. A first line 32 of solder balls of the ball grid array 30 separates semiconductor die 10 from both of semiconductor dies 11, 12. In a similar manner, a second line 33 of solder balls of the ball grid array 30 separates semiconductor die 11 from semiconductor die 12. The first line 32 of solder balls is provided to reduce the likelihood of RF electromagnetic radiation emissions from die 10 affecting operation of adjacent dies 11, 12 during their operation, and vice versa. Similarly, the second line 33 of solder balls is provided to reduce the likelihood of RF electromagnetic radiation emissions from die 11 affecting operation of adjacent die 12 during their operation, and vice versa. Upper and lower side mold structures 41, 42 (shown in FIG. 2) are arranged over the respective upper and lower surfaces 21, 22 of the substrate panel 20 to encapsulate the electronic modules mounted on both surfaces 21, 22 of the substrate panel 20, such as the dies 10, 11, 12 (on the lower surface 22) and the flip chip and filter (on the upper surface 21).

As the solder balls of the ball grid array 30 are centrally positioned on their respective metal contact pads 31, this imposes limitations on the position of the solder balls on the substrate panel 20 (including the lines 32, 33 of solder balls), in turn imposing limitations on the position and size of the semiconductor dies 10, 11, 12 positioned on the substrate panel between the solder balls. Further, the dimensions of the solder balls of the ball grid array 30 are dictated by their primary function of serving as a means for connecting the electronic package 1 to a separate circuit board (not shown). The spatial separation between successive solder balls 30 in the first and second lines 32, 33 of solder balls limits the level of RF electromagnetic shielding that can be provided.

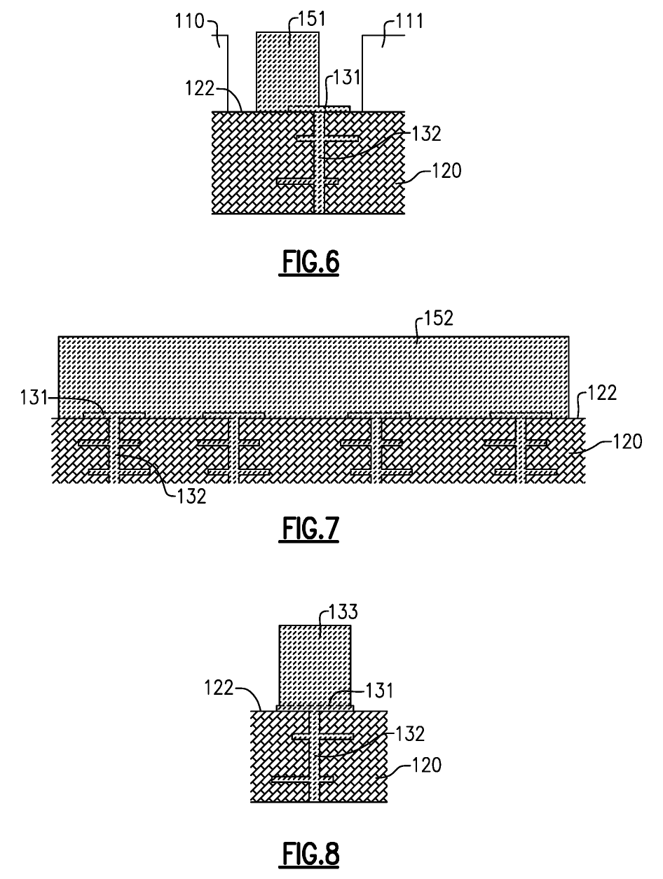

FIG. 3 is a plan schematic view of the bottom side of a first example of an electronic package 100 according to aspects of the present disclosure. FIG. 4 is a cross-sectional schematic view through section B-B of the electronic package 100 of FIG. 3. FIG. 5 is a cross-sectional schematic view through section C-C of the electronic package 100 of FIG. 3. The electronic package 100 is a dual-sided electronic package. The electronic package 100 may also be referred to as a dual-sided molded package module, or a package module.

The electronic package 100 has a substrate panel 120, the panel having a thickness defined between opposing upper and lower surfaces 121, 122. The substrate panel 120 is generally planar in form. The substrate panel 120 may have a laminate construction. The substrate panel 120 may include a ceramic substrate. The ceramic substrate may include a low temperature co-fired ceramic substrate. However, it will be appreciated that other materials may be used to form the substrate panel 120. The substrate panel 120 may define a printed circuit board.

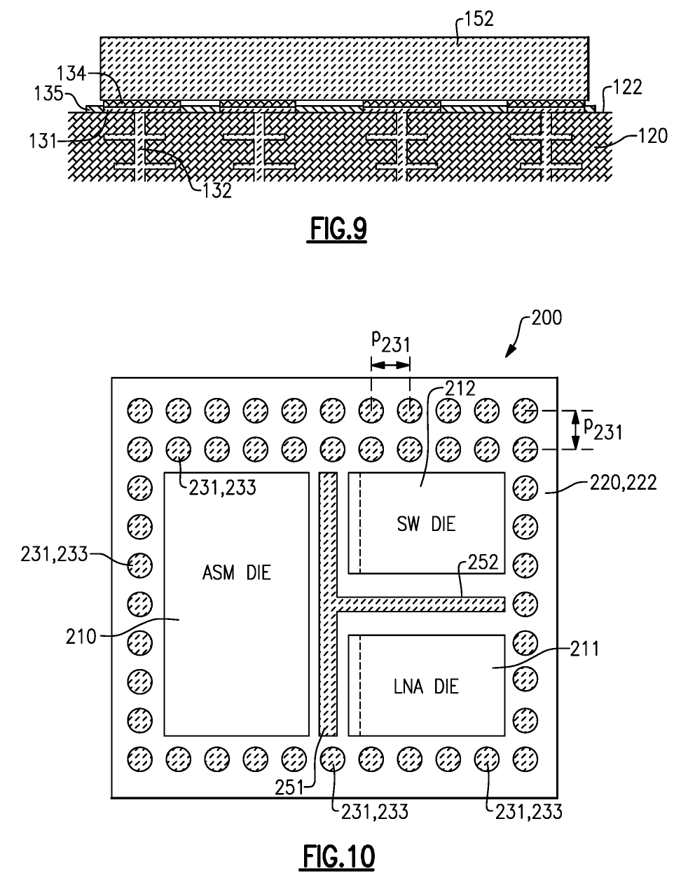

Electronic modules are mounted on both the upper and lower surfaces 121, 122 of the substrate panel 120, as shown in FIGS. 4 and 5. The electronic modules (for example, dies 110, 111, 112) may be mounted to the substrate panel 120 using any suitable form of surface-mount technology. The electronic modules mounted to the lower surface 122 of the substrate panel 120 include Antenna Switch Module (ASM) die 110, Low Noise Amplifier (LNA) die 111 and Switch (SW) die 112. However, it will be appreciated that other forms of electronic module may be arranged on the lower surface 122 of the substrate panel 120. The electronic module may be any electronic component, semiconductor component, circuit, die or similar. A first electrically conductive shield wall 151 is arranged on the lower surface 122 of the substrate panel 120. A first portion of the length of the shield wall 151 is positioned between ASM die 110 and LNA die 111. A second portion of the length of the shield wall 151 is positioned between ASM die 110 and SW die 112. A second electrically conductive shield wall 152 is arranged on the lower surface 122 of the substrate panel 120 between LNA die 111 and SW die 112. The electrically conductive shield walls 151, 152 are formed of copper, in common with a grid of contact pads 131 provided on the lower surface 122 of the substrate panel 120 and vias 132 provided within the interior of the substrate panel 120. FIGS. 6 to 8 show each contact pad 131 integrally formed as a single piece with a corresponding via 132. Successive ones of the contact pads of the grid of contact pads 131 are spaced apart from each other by a predetermined pitch ‘p₁₃₁’. In alternative embodiments, the shield walls 151, 152 may be formed from other electrically conductive materials, for example, metallic materials other than copper. The shield walls 151, 152 shown in FIG. 3 are each linear and continuous over their length. In other embodiments, the shield walls 151, 152 may have any desired shape, for example being non-linear or curved in profile. In other embodiments, one of the shield walls 151, 152 may be formed to substantially surround one of the dies 111, 112, 113. The first shield wall 151 has a greater thickness than that of the second shield wall 152. A higher wall thickness is employed for the first shield wall 151 in view of the ASM die 110 being more susceptible to RF interference from either of LNA die 111 and/or SW die 112 (or vice versa), compared to the susceptibility of LNA die 111 to RF interference from SW die 112 (or vice versa). A clearance or gap ‘X’ is provided between the first and second shield walls 151, 152, as shown in FIG. 3. As will be described in further detail below, the shield walls 151, 152 are arranged or formed on the surface of different ones of the contact pads 131, with the shield walls 151, 152 spanning adjacent ones of the contact pads 131. Interconnection elements 133 are formed on each of the contact pads 131 not occupied by the shield walls 151, 152. The interconnection elements 133 are provided to allow for connection of the electronic package 100 to a separate circuit board, although they may also serve as signal paths for transmission of electrical or data signals. The interconnection elements 133 are in the form of posts formed of copper, in common with the material used for the contact pads 131. However, in other embodiments, metallic materials other than copper may be used for the posts 133. For the illustrated embodiment, the posts 133 are cylindrical in form. However, in other embodiments, the interconnection elements 133 may have a different geometric profile.

Upper and lower side mold structures 141, 142 are applied over the respective upper and lower surfaces 121, 122 of the substrate panel 120 to encapsulate components mounted on the surfaces 121, 122. The upper side mold structure 141 is initially applied to fully encapsulate all of the components mounted on the upper surface 121 of the substrate panel 120. Similarly, the lower side mold structure 142 is initially applied to fully encapsulate all of the components mounted on the lower side 122 of the substrate panel 120. However, in a subsequent step, a grinding operation or similar is performed to expose surfaces of the interconnection elements 133 and shield walls 151, 152 through the lower side mold structure 142. A similar operation is also performed to remove some of the upper side mold structure 141 to expose a surface of the flip chip. FIGS. 4 and 5 show the electronic package 100 after removal of material from the upper and lower side mold structures 141, 142. An epoxy material may be used for the upper and/or lower side mold structures 141, 142, although it will be appreciated that in alternative embodiments other materials may be used for the mold structures 141, 142 that provide similar levels of physical protection to the components mounted to the substrate panel 120.

FIG. 6 is a cross-sectional schematic view through section D-D of the bottom half of the electronic package 100 of FIG. 3, showing how the first shield wall 151 is formed and positioned on the lower surface 122 of the substrate panel 120 between ASM die 110 and LNA die 111. FIG. 7 is a cross-sectional schematic view through section E-E of the bottom half of the electronic package 100 of FIG. 3, showing how the second shield wall 152 is formed and positioned on the lower surface 122 of the substrate panel 120. FIG. 6 shows the full thickness of the first shield wall 151. FIG. 7 shows the full length of the second shield wall 152. Each of the shield walls 151, 152 is formed by a process of electroplating onto the surface of respective copper contact pads 131 to progressively build up and form the walls 151, 152. The use of electroplating has the effect that the shield walls 151, 152 are integrally formed as part of the structure of the copper contact pads 131, thereby avoiding the need to employ solder to fuse a separate shield wall structure onto the contact pads 131. As can be seen from FIG. 6, the first shield wall 151 is formed to be offset from the geometric center of the surface of the contact pads 131 associated with the shield wall 151. The offsetting of the first shield wall 151 away from the center of the contact pads 131 provides additional space to allow the LNA die 111 to be larger in size compared to if a shield wall 151 of the same thickness as shown in FIG. 6 were instead centrally located on the corresponding contact pads 131. A broken outline is shown in FIG. 4 to indicate the maximum size of LNA die 111’ that could be employed if the shield wall 151 were instead confined to being centrally located on the corresponding contact pads 131. The shield walls 151, 152 are formed to extend away from the lower surface 122 of the substrate panel 120 to a height of around 120 microns (0.120 mm). However, in other embodiments the shield walls 151, 152 may have a height which is lesser or greater in value. First shield wall 151 is formed to have a thickness of 250 microns (0.250 mm), whereas second shield wall 152 is formed to have a thickness of 125 microns (0.125 microns). However, it will be appreciated that the thickness selected for the shield walls 151, 152 will be dependent on the sensitivity of the electronic modules (for example, dies 110, 111, 112) of the electronic package 100 to RF interference. The height selected for the shield walls 151, 152 will be dependent on the height of the adjacent electronic modules (for example, dies 110, 111, 112) disposed on the lower surface 122 of the substrate panel 120. It will be appreciated that minimizing the height of electronic modules (for example, dies 110, 111, 112) mounted on the lower surface 122 of the substrate panel 120 will also permit the shield wall height to be kept to a minimum, thereby helping to reduce the overall thickness of the electronic package 100.

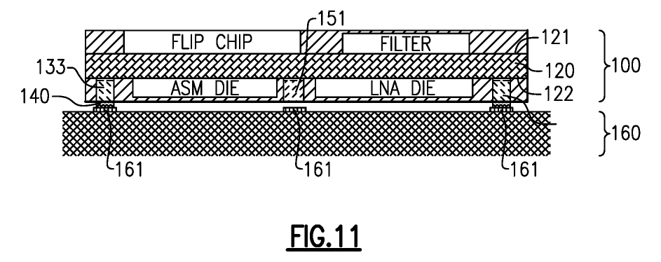

FIG. 8 is a cross-sectional schematic view through section F-F of the bottom half of the electronic package of FIG. 3, showing how the posts 133 are formed and positioned on respective ones of the contact pads 131 provided on the lower surface 122 of the substrate panel 120. Each copper post 133 is formed by electroplating onto a surface of a corresponding one of the copper contact pads 131 to progressively build up and form the copper post. The copper posts 133 are formed to a height of 120 microns (0.120 mm), in common with the shield walls 151, 152. However, it will be appreciated that the height of the posts 133 will be dependent on the height of the electronic modules mounted to the lower surface 122 of the substrate panel 120.

FIG. 9 is a cross-sectional schematic view through section E-E of the bottom half of the electronic package 100 of FIG. 3, showing an alternative embodiment of the electronic package 100 in which the shield wall 152 is fused to different contact pads 131 by the use of intermediate portions of solder 134. FIG. 9 shows the contact pads 131 exposed through apertures formed in a layer of solder mask 135 applied to the lower surface 122 of the substrate panel 120. So, in the embodiment of FIG. 9, the shield wall 152 is provided as a separate and distinct structural feature to the contact pads 131. It will be appreciated that for this alternative embodiment, the shield wall 151 and/or the copper posts 133 may also be fused to respective contact pads 131 in the same manner.

FIGS. 6 to 9 do not show the lower side mold structure 142 for ease of understanding of these figures.

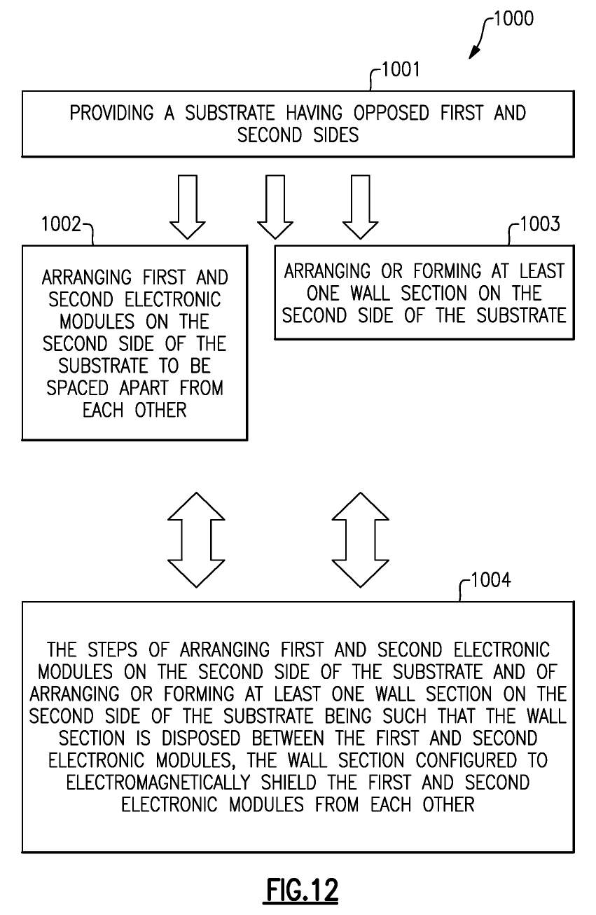

FIG. 10 is a plan schematic view of the bottom side of a further example of an electronic package 200 according to aspects of the present disclosure. Features in common with the electronic package 100 of FIGS. 3 to 8 are referred to with like reference signs but commencing with numeral “2” instead of “1”. The electronic package 200 differs from electronic package 100 in having the first and second shield walls 251, 252 integrally formed as a single piece, without there being a gap or clearance between one shield wall and the other.

FIG. 11 is a schematic view showing the electronic package 100 of FIG. 3 mounted to a surface of a separate circuit board 160 to form an electronic sub-assembly, the electronic package 100 shown through section B-B of FIG. 3. Exposed surfaces of the copper posts 133 permit the electronic package 100 to be coupled to the circuit board 160. More specifically, intermediate portions of solder 140 are provided between exposed surfaces of the copper posts 133 and corresponding contact pads 161 provided on the surface of the circuit board 160. In an alternative embodiment to that shown in FIG. 11, an intermediate portion of solder 140 may also be used to couple an exposed face of the shield wall 151 to a corresponding contact pad 161 of the circuit board 160.

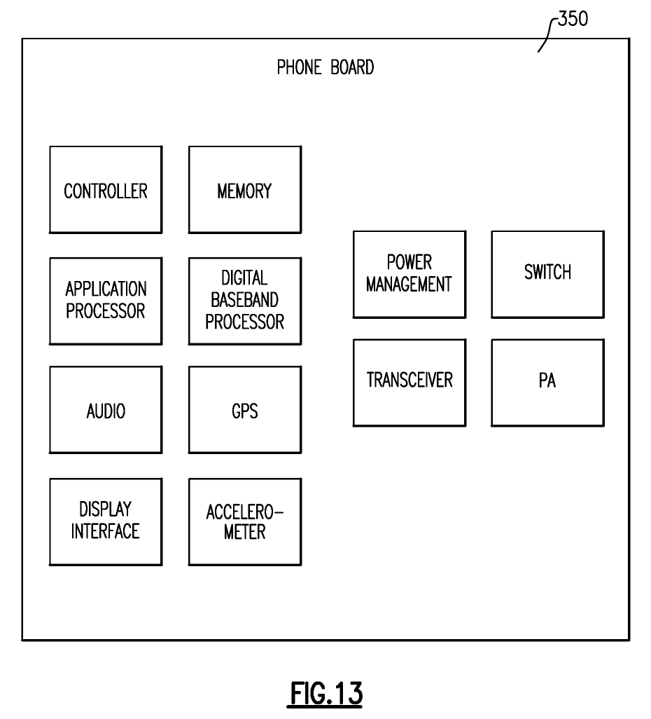

FIG. 12 is a flow chart illustrating an exemplary method 1000 of manufacturing an electronic package according to aspects of the present disclosure. The method 1000 may be applied to any of the electronic packages referred to in preceding paragraphs of this disclosure, such as electronic packages 100 or 200. The steps of the method 1000 may also be understood by reference to the preceding paragraphs of the present disclosure describing the structure and formation of electronic packages 100 or 200.

The method has a step 1001 comprising providing a substrate having opposed first and second sides. By way of example, the substrate panel may be provided in the form of substrate panel 120 having opposed surfaces 121, 122, as described in preceding paragraphs.

Step 1001 is followed by steps 1002 and 1003. It will be understood that in a first embodiment step 1002 may be performed before step 1003. It will be understood that in a second embodiment step 1003 may be performed before step 1002. It will further be understood that in a third embodiment steps 1002 and 1003 may be performed substantially simultaneously with each other.

Step 1002 comprises arranging first and second electronic modules (for example, any of ASM die 110, LNA die 111, and SW die 112 as described in preceding paragraphs) on the second side of the substrate to be spaced apart from each other. Third and fourth electronic modules may be arranged on the first side of the substrate to be spaced apart from each other. The first and second electronic modules may be mounted to the second side of the substrate using any suitable form of surface-mount technology. Step 1003 comprises arranging or forming at least one wall section on the second side of the substrate. For example, step 1003 may comprise arranging or forming at least one wall section on the second side of the substrate such that the wall section is coupled to two or more of a plurality of interfaces provided on the second side of the substrate. By way of example, the wall section may be in the form of wall section 151 and/or wall section 152, with the interfaces being in the form of the contact pads 131 arranged on the lower surface 122 of substrate panel 120. The wall section may be formed by electroplating onto an interface provided on the substrate; for example, as described in relation to the formation of the first and second shield walls 151, 152 by electroplating onto the surfaces of contact pads 131. Alternatively, the wall section may be a separate structural entity fused to an interface provided on the substrate, for example, by use of solder.

As noted in 1004 of FIG. 12, steps 1002 and 1003 are performed such that the wall section is disposed between the first and second electronic modules.

Further, the wall section is configured to electromagnetically shield the first and second electronic modules from each other. As can be understood from preceding paragraphs of the present disclosure, the wall section may be formed from an electrically conductive material. Copper is an example of a particularly suitable material for the wall section, although other electrically conductive materials may be employed.

FIG. 13 shows an embodiment of a circuit board 350, such as a wireless phone board, which may include one or more dual-sided molded package modules within the scope of the present disclosure, such as the dual-sided molded package module 100 of FIG. 3. Non-limiting examples of package modules that can benefit from such packaging features as disclosed herein include, but are not limited to, a controller module, an application processor module, an audio module, a display interface module, a memory module, a digital baseband processor module, a global positioning system (GPS) module, an accelerometer module, a power management module, a transceiver module, a switching module, and a power amplifier module. So, each of the package modules depicted for the wireless phone board 350 of FIG. 13 may correspond to the dual-sided molded package module 100 of FIG. 3.

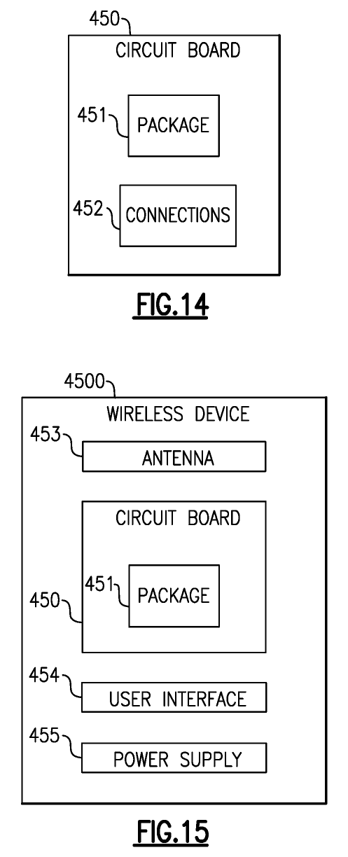

FIG. 14 schematically depicts a circuit board 450 having a package module 451 mounted thereon in the manner described herein; by way of example, the package module 451 may correspond to the dual-sided molded package module of FIG. 3. The circuit board 450 may also include other features, such as a plurality of connections 452 to facilitate operations of various packages mounted thereon.

FIG. 15 schematically depicts a wireless device 4500 (for example, a cellular phone) having a circuit board 450 (for example, a phone board). The circuit board 450 is shown to include a package 451 mounted thereon in the manner described herein; for example, the package 451 may correspond to the dual-sided molded package module 100 of FIG. 3. The wireless device 4500 is shown to further include other components, such as an antenna 453, a user interface 454, and a power supply 455.

It will be noted that the figures are for illustrative purposes only, and are not to scale.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the disclosure. Accordingly, the foregoing description and drawings are by way of example only, and the scope of the disclosure should be determined from proper construction of the appended claims, and their equivalents.

1. An electronic package for mounting to a circuit board, the electronic package comprising:
a substrate having opposed first and second sides;
first and second electronic modules disposed on the second side of the substrate and spaced apart from each other;
third and fourth electronic modules disposed on the first side of the substrate and spaced apart from each other; and
at least one wall section disposed between the first and second electronic modules, the at least one wall section formed of an electrically conductive material and mounted on the second side of the substrate, the at least one wall section being configured to electromagnetically shield the first and second electronic modules from each other.

2. The electronic package of claim 1, wherein the at least one wall section is coupled to at least one of a plurality of interfaces formed of an electrically conductive material and provided on the second side of the substrate.

3. The electronic package of claim 2, wherein the at least one wall section is integrally formed as a unitary piece with the at least one of the plurality of interfaces.

4. The electronic package of claim 2, wherein the at least one wall section is offset from a center of the at least one of the plurality of interfaces.

5. The electronic package of claim 2, wherein an intermediate element couples the at least one wall section to the at least one of the plurality of interfaces.

6. The electronic package of claim 1, wherein the first side of the substrate corresponds to a top surface of the electronic package and the second side of the substrate corresponds to a bottom surface of the electronic package, the bottom surface of the electronic package being configured for mounting to a surface of a separate circuit board.

7. The electronic package of claim 1, wherein the at least one wall section comprises a plurality of wall sections, first and second ones of the plurality of wall sections being aligned substantially perpendicular to each other.

8. The electronic package of claim 1, wherein one or more solder portions are disposed on an exposed surface of the at least one wall section for coupling the electronic package to a separate circuit board.

9. The electronic package of claim 1, wherein a second side mold structure extends over at least part of the second side of the substrate to at least partially encapsulate the at least one wall section, a face of the at least one wall section being exposed through the second side mold structure.

10. The electronic package of claim 9, wherein the exposed face of the at least one wall section is flush with an exposed surface of the second side mold structure.

11. An electronic device including an electronic sub-assembly, the electronic sub-assembly comprising:
a circuit board; and
an electronic package mounted to the circuit board, the electronic package including a substrate having opposed first and second sides, first and second electronic modules disposed on the second side of the substrate to be spaced apart from each other, and at least one wall section disposed between the first and second electronic modules, the at least one wall section mounted on the second side of the substrate, the at least one wall section configured to electromagnetically shield the first and second electronic modules from each other.

12. A method for manufacturing an electronic package for mounting to a circuit board, the method comprising:
providing a substrate having opposed first and second sides;
arranging first and second electronic modules on the second side of the substrate to be spaced apart from each other;
arranging third and fourth electronic modules on the first side of the substrate to be spaced apart from each other; and
arranging or forming at least one electrically conductive wall section on the second side of the substrate between the first and second electronic modules, the at least one wall section configured to electromagnetically shield the first and second electronic modules from each other.

13. The method of claim 12, wherein arranging or forming the at least one wall section on the second side of the substrate comprises coupling the at least one wall section to at least one of a plurality of interfaces provided on the second side of the substrate.

14. The method of claim 13, wherein arranging or forming the at least one wall section on the second side of the substrate is performed such that the at least one wall section is offset from a center of the at least one of the plurality of interfaces.

15. The method of claim 12, wherein arranging or forming the at least one wall section on the second side of the substrate is performed such that the at least one wall section extends around at least 50%, or at least 60%, or at least 70% of a perimeter of one of the first and second electronic modules.

16. The method of claim 15, wherein arranging or forming the at least one wall section on the second side of the substrate is performed such that the at least one wall section extends around an entire perimeter of the one of the first and second electronic modules.

17. The method of claim 12, wherein arranging or forming the at least one wall section on the second side of the substrate comprises arranging or forming a plurality of wall sections on the second side of the substrate, the first and second electronic modules being arranged on the second side of the substrate and the plurality of wall sections being arranged or formed on the second side of the substrate such that the plurality of wall sections are successively arranged to extend around an entire perimeter of one of the first and second electronic modules.

18. The method of claim 12, further comprising providing one or more solder portions on an exposed surface of the at least one wall section for coupling the electronic package to a separate circuit board.

19. The method of claim 12, further comprising arranging a second side mold structure over at least part of the second side of the substrate to fully encapsulate the at least one wall section within the second side mold structure.

20. The method of claim 19, further comprising removing a portion of the second side mold structure to expose a face of the at least one wall section through the second side mold structure such that the exposed face of the at least one wall section is flush with an exposed surface of the second side mold structure and disposing one or more solder portions on the exposed face of the at least one wall section for coupling the electronic package to a separate circuit board.
